(19) United States
(12) Patent Application Publication
(10) Pub. No.: US 2019/0064278 A1
(43) Pub. Date: Feb. 28, 2019

(54) IMPEDANCE ESTIMATING APPARATUS

(71) Applicant: TOYOTA JIDOSHA KABUSHIKI KAISHA, Toyota-shi (JP)

(72) Inventors: Yasumasa OGUMA, Shizuoka-ken (JP); Tetsuya OSAKA, Tokyo (JP); Shingo TSUDA, Tokyo (JP); Kazuaki UTSUMI, Tokyo (JP); Tokihiko YOKOSHIMA, Tokyo (JP); Daikichi MUKOYAMA, Tokyo (JP)

(73) Assignee: TOYOTA JIDOSHA KABUSHIKI KAISHA, Toyota-shi (JP)

(21) Appl. No.: 16/101,592

(22) Filed: Aug. 13, 2018

(30) Foreign Application Priority Data
Aug. 24, 2017 (JP) 2017-161206

(51) Int. Cl. G01R 31/36

(52) U.S. Cl. CPC G01R 31/3662; G01R 31/3675; G01R 31/3651

(57) ABSTRACT

An impedance estimating apparatus is provided with: a deriving device configured to derive a slope function, on the basis of a value of a complex impedance of a battery at a predetermined frequency out of values obtained at a plurality of different temperatures and on the basis of a temperature of the battery when the complex impedance is obtained, wherein the slope function indicates a relation between the value of the complex impedance at the predetermined frequency and an inverse of the temperature of the battery; and an estimator configured to estimate a value of the complex impedance at the predetermined frequency corresponding to a desired temperature of the battery by using the slope function.

### CROSS-REFERENCE TO RELATED APPLICATIONS

This application is based upon and claims the benefit of priority of the prior Japanese Patent Application No. 2017-161206, filed on Aug. 24, 2017, the entire contents of which are incorporated herein by reference.

### BACKGROUND

### 1. Technical Field

Embodiments of the present disclosure relate to an impedance estimating apparatus configured to estimate an impedance of a battery mounted on a vehicle or the like.

### 2. Description of the Related Art

On this of apparatus, an impedance is estimated to know, for example, a charge amount of a battery. For example, International Publication No. WO2013/114669 (Patent Literature 1) discloses a proposed technique/technology in which the charge amount of the battery is detected from a slope angle of a straight line connecting two or more complex impedances with different frequencies.

Moreover, Japanese Patent Application Laid Open No. 2014-126532 (Patent Literature 2) discloses a technique/technology in which a response signal to an inputted rectangular wave signal is Fourier-transformed and in which an impedance characteristic of an electrochemical cell is calculated on the basis of a calculated frequency characteristic. International Publication No. WO2013/018641 (Patent Literature 3) discloses a technique/technology in which an internal impedance is measured by using a signal with a frequency that is hardly followed by ions in a power storage apparatus and in which an internal temperature of the power storage apparatus is calculated from a measured value. Japanese Patent Application Laid Open No. 2008-157757 (Patent Literature 4) discloses a technique/technology in which an influence on the internal impedance caused by a change in a charging rate and temperature of the battery is corrected to estimate the internal impedance at a predetermined temperature and a predetermined charging rate.

The impedance of the battery is caused by charge transfer or the like, and thus has a significant temperature dependence. Therefore, in order to accurately estimate the impedance of the battery by using the techniques/technologies described in the above Patent Literatures, it is desirable to perform an estimation process after setting the temperature of the battery at a reference temperature, i.e., under a predetermined temperature condition.

The temperature of the battery, however, varies depending on a use state of the battery. Thus, for example, if the impedance of the battery mounted on the vehicle is to be estimated during running of the vehicle, it is hard to perform the estimation process after setting the temperature of the battery at the reference temperature. Therefore, when the techniques/technologies described in the above Patent Literatures are used, the impedance of the battery may not be accurately detected due to the variation in temperature of the battery, which is technically problematic.

### SUMMARY

In view of the aforementioned problems, it is therefore an object of embodiments of the present disclosure to provide an impedance estimating apparatus configured to accurately estimate the impedance of the battery.

The above object of embodiments of the present disclosure can be achieved by an impedance estimating apparatus provided with: a deriving device configured to derive a slope function, on the basis of a value of a complex impedance of a battery at a predetermined frequency out of values obtained at a plurality of different temperatures and on the basis of a temperature of the battery when the complex impedance is obtained, wherein the slope function indicates a relation between the value of the complex impedance at the predetermined frequency and an inverse of the temperature of the battery; and an estimator configured to estimate a value of the complex impedance at the predetermined frequency corresponding to a desired temperature of the battery by using the slope function.

The above object of embodiments of the present disclosure can be achieved by another impedance estimating apparatus provided with: a deriving device configured to derive a plurality of slope functions, on the basis of values of complex impedances of a battery at a plurality of frequencies out of values obtained at a plurality of different temperatures and on the basis of temperatures of the battery when the complex impedances are obtained, in a frequency area higher than an area of Cole-Cole plotted complex impedances that belongs to ion diffusion, wherein each of the plurality of slope functions indicates a relation between the values of the complex impedances at the plurality of frequencies and inverses of the temperatures of the battery; and an estimator configured (i) to estimate real components at the plurality of frequencies that form an arc component of the complex impedances by using the plurality of slope functions and to estimate an imaginary component at a peak frequency of the arc component of the complex impedances by using a slope function corresponding to the peak frequency from among the plurality of slope functions, (ii) to estimate the arc component of the complex impedances from the estimated real components and the estimated imaginary component, and (iii) to estimate a value of the complex impedance corresponding to a desired temperature of the battery from the estimated arc component.

### BRIEF DESCRIPTION OF THE DRAWINGS

FIG. 1 is a block diagram illustrating a configuration of an impedance estimating apparatus according to a first embodiment;

FIG. 2 is a graph illustrating waveforms of complex impedances measured at 20 degrees C., 25 degrees C., and 30 degrees C.;

FIG. 3 is a graph illustrating waveforms of the complex impedances measured at 40 degrees C., 45 degrees C., and 50 degrees C.;

FIG. 4 is a flowchart illustrating a flow of operations of the impedance estimating apparatus according to the first embodiment;

FIG. 5 is a graph illustrating a relation between an absolute value of the complex impedance and an inverse of temperature;

FIG. 6 is a graph illustrating a relation between a real component of the complex impedance and the inverse of the temperature;

FIG. 7 is a graph illustrating a relation between an imaginary component of the complex impedance and the inverse of the temperature;

FIG. 8 is graphs respectively illustrating relations between values of the complex impedances measured in different SOCs and the inverses of the temperatures;

FIG. 9 is a graph illustrating a partially enlarged arc component of a Cole-Cole plot;

FIG. 10 is a flowchart illustrating a flow of operations of an impedance estimating apparatus according to a second embodiment;

FIG. 11 is a graph illustrating a relation between the real component of the complex impedance and the inverse of the temperature in a frequency band corresponding to the arc component; and

FIG. 12 is a graph illustrating a relation between the imaginary component of the complex impedance and the inverse of the temperature in the frequency band corresponding to the arc component.

### DETAILED DESCRIPTION OF THE EMBODIMENTS

An impedance estimating apparatus according to embodiments of the present disclosure will be explained with reference to the drawings.

### First Embodiment

An impedance estimating apparatus 100 according to a first embodiment will be explained. The following is an example in which the impedance estimating apparatus 100 is configured to estimate an impedance of a battery 10 of a vehicle.

(1) Configuration of Apparatus

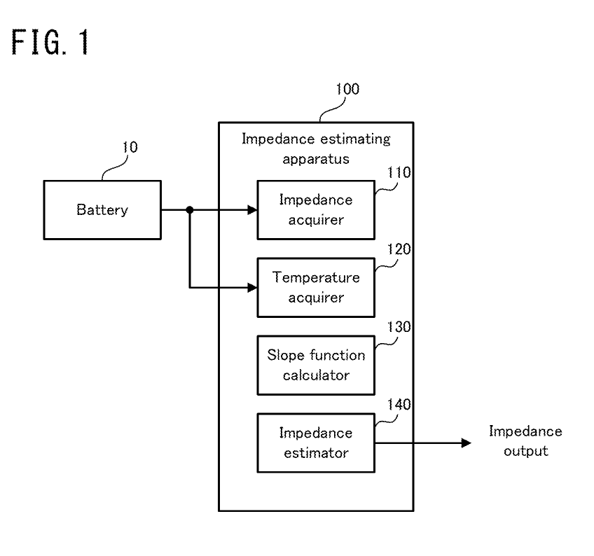

Firstly, a configuration of the impedance estimating apparatus 100 according to the first embodiment will be explained with reference to FIG. 1. FIG. 1 is a block diagram illustrating the configuration of the impedance estimating apparatus 100 according to the first embodiment.

As illustrated in FIG. 1, the impedance estimating apparatus 100 according to the first embodiment is an electronic unit electrically connected to the battery 10 of the vehicle, and is configured to estimate the impedance, i.e., a complex impedance, of the battery 10. The battery 10 is a specific example of the “battery” in Supplementary Note described later, and is configured as a chargeable aqueous secondary battery, such as, for example, a lithium ion battery.

The impedance estimating apparatus 100 is provided with an impedance acquirer 110, a temperature acquirer 120, a slope function calculator 130, and an impedance estimator 140, as logical or physical processing blocks realized therein.

The impedance acquirer 110 is configured to obtain the complex impedance of the battery 10. The impedance acquirer 110 is configured to obtain the complex impedance, for example, by applying an alternating current (AC) voltage to the battery 10 while changing a frequency. A method of obtaining the complex impedance can use the exiting technique/technology, as occasion demands, and a detailed explanation herein will be thus omitted. The complex impedance of the battery 10 obtained by the impedance acquirer 110 may be outputted to the slope function calculator 130.

The temperature acquirer 120 is configured to obtain a temperature of the battery 10, or preferably, a temperature of an electrode. The temperature acquirer 120 is particularly configured to obtain the temperature when the impedance acquirer 110 obtains the complex impedance of the battery 10. A method of obtaining the temperature can use the exiting technique/technology, as occasion demands, and a detailed explanation herein will be thus omitted. The temperature of the battery 10 obtained by the temperature acquirer 120 may be outputted to the slope function calculator 130.

The slope function calculator 130 is a specific example of the “deriving device” in Supplementary Notes described later, and is configured to derive a slope function indicating a relation between the complex impedance of the battery 10 obtained by the impedance acquirer 110 and the temperature of the battery 10 obtained by the temperature acquirer 120. The slope function, which will be detailed later, is a function indicating that the complex impedance of the battery 10 and an inverse of the temperature of the battery 10 are in a linear relation. The slope function calculated by the slope function calculator 130 may be outputted to the impedance estimator 140.

The impedance estimator 140 is a specific example of the “estimator” in Supplementary Notes described later, and is configured to estimate the complex impedance of the battery 10 at a predetermined reference temperature by using the slope function calculated by the slope function calculator 130. More specifically, the impedance estimator 140 is configured to estimate a value that is to be obtained if the battery 10 is at the predetermined reference temperature, from the complex impedance of the battery 10 obtained by the impedance acquirer 110. The value of the complex impedance estimated by the impedance estimator 140 may be outputted to the outside of the apparatus, and may be used as a parameter for estimating a current state of the battery 10, such as, for example, a state of charge (SOC) and a state of health (SOH).

(2) Temperature Dependence of Complex Impedance and Problems

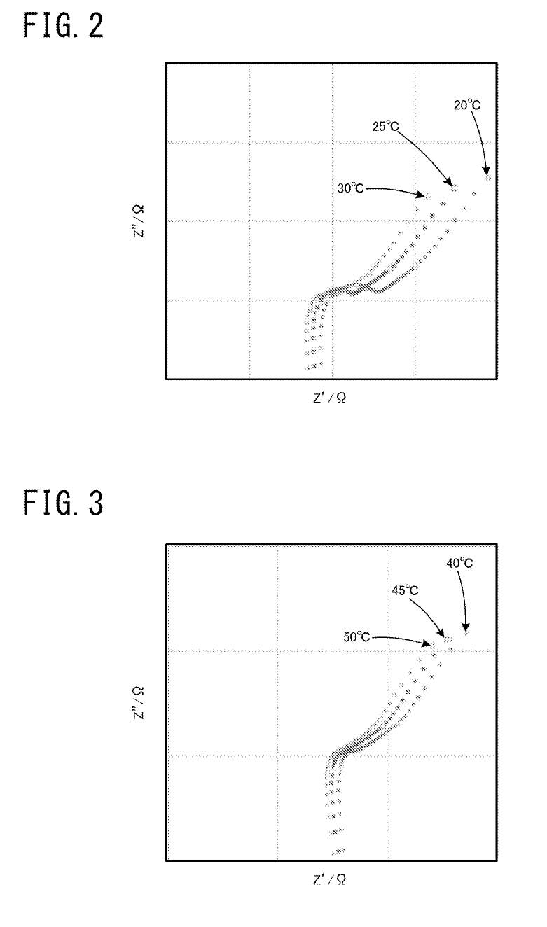

Next, a temperature dependence of the complex impedance of the battery 10 will be explained with reference to FIG. 2 and FIG. 3. FIG. 2 is a graph illustrating waveforms of complex impedances measured at 20 degrees C., 25 degrees C., and 30 degrees C. FIG. 3 is a graph illustrating waveforms of the complex impedances measured at 40 degrees C., 45 degrees C., and 50 degrees C. Data illustrated in FIG. 2 and FIG. 3 is measured when the battery 10 has a SOC of 95%.

As illustrated in FIG. 2 and FIG. 3, when complex impedances obtained at temperatures of the battery 10 of 20 degrees C., 25 degrees C., and 30 degrees C. and 40 degrees C., 45 degrees C., and 50 degrees C. are plotted on a complex plane, the complex impedances are drawn as different curves that are shifted to the right side with decreasing temperature. This indicates that the complex impedance of the battery 10 has a significant temperature dependence. The temperature dependence of the complex impedance is caused by diffusion of lithium ions and charge transfer inside the battery 10

As described above, the complex impedance of the battery 10 significantly varies depending on the temperature of the battery 10 when measured. Thus, if the state of the battery 10 is estimated by using the complex impedance, it is preferable to use the complex impedance measured at the predetermined reference temperature. In other words, it is preferable to use the complex impedance measured under a predetermined temperature condition. It is, however, not easy to set the temperature of the battery 10 at the predetermined reference temperature before the measurement. In particular, during the running of the vehicle equipped with the battery 10, the temperature of the battery 10 rises or falls due to a charging/discharging operation. It is thus hard to maintain the battery 10 at the reference temperature.

To solve the aforementioned problems, a possible method is to convert or correct the complex impedance obtained at any temperature to the complex impedance obtained at the reference temperature. However, if the existing technique/technology is used to convert the complex impedance, a relatively advanced and complicated process, such as Fitting analysis, is required. Thus, for example, if the complex impedance is measured in real time on a running vehicle or the like, it is not easy to convert at each time the complex impedance to a value corresponding to the reference temperature.

The impedance estimating apparatus 100 according to the first embodiment is configured to perform operations detailed below, to solve the aforementioned problems.

(3) Explanation of Operation

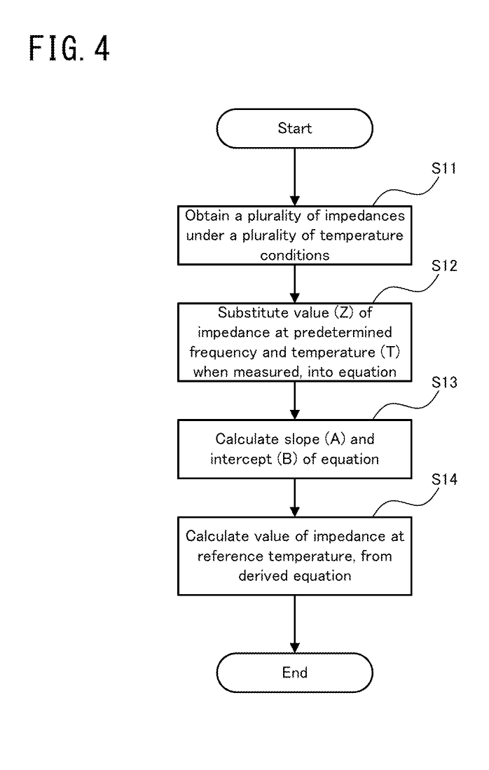

The operations performed by the impedance estimating apparatus 100 according to the first embodiment will be explained with reference to FIG. 4. FIG. 4 is a flowchart illustrating a flow of the operations of the impedance estimating apparatus according to the first embodiment.

In FIG. 4, in operation of the impedance estimating apparatus 100 according to the first embodiment, a plurality of complex impedances are firstly obtained under a plurality of temperature conditions (step S11). More specifically, a complex impedance of the battery 10 is obtained by the impedance acquirer 110, and a temperature of the battery 10 at that time may be obtained by the temperature acquirer 120.

The obtained complex impedances of the battery 10 can be divided by each frequency. In the following process, complex impedances at a predetermined frequency may be obtained under the plurality of temperature conditions. In this case, an absolute value, a real component (i.e., a real part), and an imaginary component (i.e., an imaginary part) are obtained for the complex impedances at the predetermined frequency. The “predetermined frequency” here is a frequency corresponding to a slope component of Cole-Cole plotted complex impedances (i.e., a straight line part in FIG. 2 and FIG. 3).

The obtained complex impedances of the battery 10 (whose values will be hereinafter expressed as Z0) and the temperatures of the battery 10 (whose values will be hereinafter expressed as T0) when the corresponding complex impedances are obtained may be inputted to the slope function calculator 130, so that a slope function for estimating the complex impedance may be derived. The slope function calculator 130 substitutes the values Z0 of the complex impedances at the predetermined frequency of the battery 10 and the temperatures T0 of the battery 10 when the corresponding complex impedances are obtained, into a numerical expression stored in advance (i.e., a numerical expression (1) described below) (step S12).

According to studies by the present inventors, it has been found that a relation of the following equation (1) is established between a value Z of the complex impedance at the predetermined frequency and a temperature T of the battery 10.

log Z=A×(1/T)+B (1)

Thus, if a slope A and an intercept B are obtained after the temperatures T0 and the values Z0 of the complex impedance of the battery actually obtained are substituted into the equation (1) (step S13), it is possible to derive a slope function indicating the relation between the temperature T and the value Z of the complex impedance of the battery 10.

The slope function derived in this manner may be outputted to the impedance estimator 140 and may be used to estimate the value Z of the complex impedance corresponding to a predetermined temperature. Specifically, the impedance estimator 140 substitutes the predetermined reference temperature into T in the slope function, thereby calculating the value Z of the complex impedance corresponding to the predetermined reference temperature (step S14).

(4) Method of Deriving Slope Function

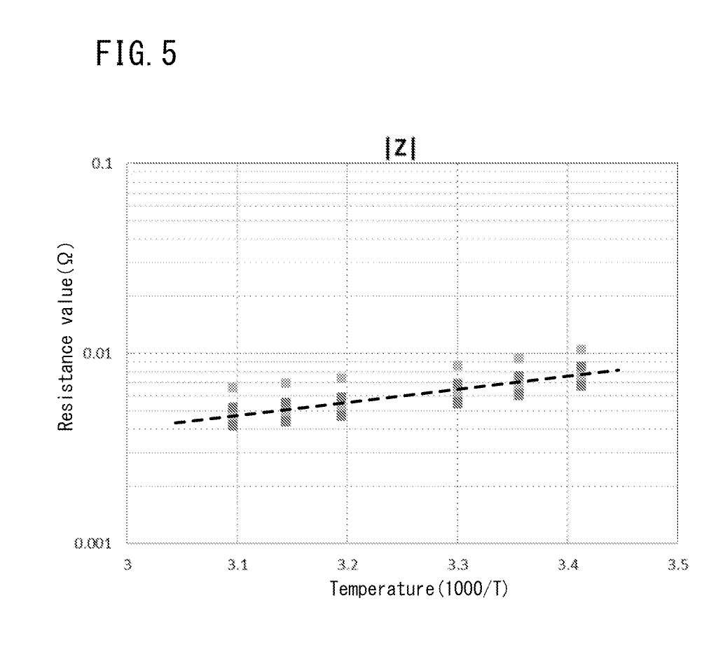

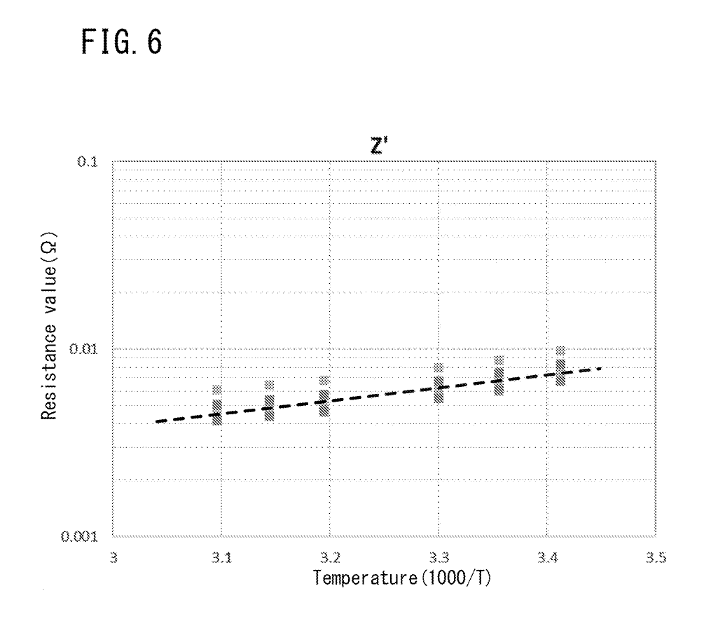

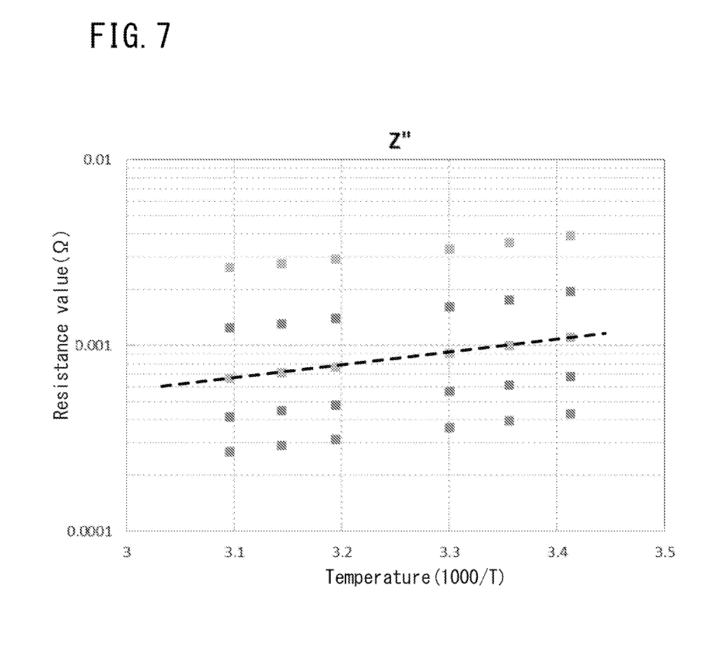

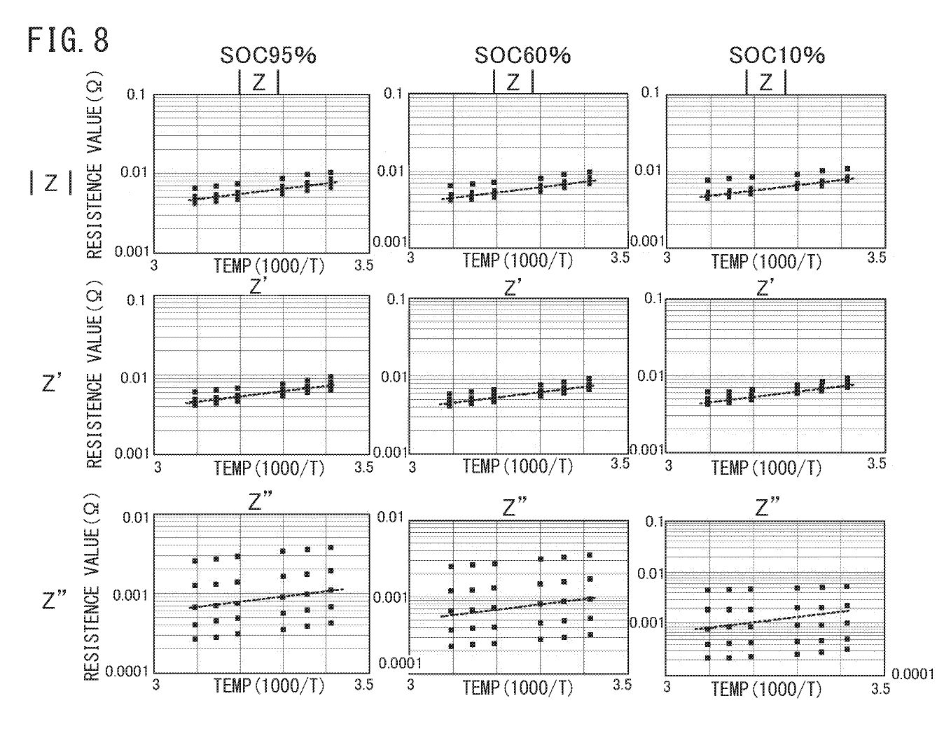

Next, a specific method of deriving the slope function described above will be explained with reference to FIG. 5 to FIG. 8. FIG. 5 is a graph illustrating a relation between an absolute value of the complex impedance and an inverse of the temperature. FIG. 6 is a graph illustrating a relation between a real component of the complex impedance and the inverse of the temperature. FIG. 7 is a graph illustrating a relation between an imaginary component of the complex impedance and the inverse of the temperature. FIG. 8 is graphs respectively illustrating relations between values of the complex impedances measured in different SOCs and the inverses of the temperatures. A numerical value on a horizontal axis in each of FIG. 5 to FIG. 8 is a numerical value when the temperature T is measured by the absolute temperature.

As illustrated in FIG. 5 to FIG. 7, a plurality of types of slope functions are derived by using an absolute value |Z|, a real component Z′, and an imaginary component Z″ for the complex impedances. In other words, a slope function for the absolute value |Z|, a slope function for the real component Z′, and a slope function for the imaginary component Z″ are separately derived. The slope function may be not always derived for all the absolute value |Z|, the real component Z′, and the imaginary component Z″, and the slope function may be derived for at least one of the absolute value |Z|, the real component Z′, and the imaginary component Z″.

In FIG. 5, the absolute value |Z| for the complex impedances measured in a range in which the temperature T of the battery is 20 to 50 degrees C. changes linearly with respect to a variation in the temperature T.

Specifically, connecting points corresponding to the same frequency provides a straight line (refer to a dashed line in FIG. 5). As described above, if the absolute value |Z| of the complex impedance and the temperature T when the value is obtained are used and plotted to obtain an approximate straight line, which connects plotted points, the slope function can be derived for the absolute value |Z| of the complex impedance.

In FIG. 6, the real component Z′ for the complex impedances measured in the range in which the temperature T of the battery is 20 to 50 degrees C. also changes linearly with respect to the variation in the temperature T, as in the absolute value |Z| illustrated in FIG. 5. Thus, if the real component Z′ of the complex impedance and the temperature T when a value of the real component Z′ is obtained are used and plotted to obtain an approximate straight line, which connects plotted points, the slope function can be derived for the real component Z′ of the complex impedance. In FIG. 7, the imaginary component Z″ for the complex impedances measured in the range in which the temperature T of the battery is 20 to 50 degrees C. also changes linearly with respect to the variation in the temperature T, as in the absolute value |Z| illustrated in FIG. 5 and the real component Z′ illustrated in FIG. 6. Thus, if the imaginary component Z″ of the complex impedance and the temperature T when a value of the imaginary component Z″ is obtained are used and plotted to obtain an approximate straight line, which connects plotted points, the slope function can be derived for the imaginary component Z″ of the complex impedance.

In FIG. 8, straight lines corresponding to the same slope function are overlapped on graphs obtained when the temperatures T0 and the values Z0 of the complex impedances of the battery 10 are obtained in different SOCs (i.e., 95%, 60%, 10%). As can be seen, a plurality of points corresponding to the same frequency are connected by a straight line on each of the graphs of the absolute value |Z|, the real component Z′, and the imaginary component Z″. This indicates that the same slope function is derived in each of the absolute value |Z|, the real component Z′, and the imaginary component Z′, even in different SOCs.

In the imaginary component Z″, however, data for SOC 10% has a part in which the data is significantly shifted from the straight line. In other words, in the imaginary component Z″, an error that cannot be ignored possibly occurs according to measurement circumstances. Thus, in a situation in which only the absolute value |Z| and the real component Z′ are sufficient for the value Z of the impedance to be calculated, the slope function may be derived only for at least one of the absolute value |Z| and the real component Z′; namely, the slope function may not be derived for the imaginary component Z″.

In the examples illustrated in FIG. 5 to FIG. 7, the slope function is derived as the approximate straight line, which connects a plurality of points; however, the approximate straight line, i.e., the slope function, can be derived from a point if any of the slope A and the intercept B of the slope function is known. In other words, if the slope A or the intercept B of the slope function is known, it is not necessary to obtain the plurality of temperatures T0 and the plurality of values Z0 of the complex impedance. It is possible to derive the slope function only from a pair of the temperature T0 and the value Z0 of the complex impedance.

If the plurality of points are not used, it is considered that an influence of measurement errors may be increased in the measurement of the complex impedances and the temperatures of the battery 10. Specifically, it is hardly possible to remove an influence of noise by using the plurality of points. Thus, if the slope function is derived from a point, data measured at a temperature at which measurement accuracy is ensured may be used. The “temperature at which the measurement accuracy is ensured” is a temperature of the battery 10 corresponding to a situation in which an event that causes a reduction in the measurement accuracy unlikely occurs.

For example, the battery 10 may have a variation in internal temperature due to a temperature change, and the temperature T cannot be accurately measured in some cases. Thus, if data measured in this situation is used, it is hardly possible to accurately derive the slope function. Therefore, if the slope function is derived from a point, it is preferable to use data measured in a situation in which there is no variation in internal temperature of the battery 10. An example of the situation in which there is no variation in internal temperature of the battery 10 is immediately after the start of a vehicle on which the battery 10 is mounted.

(5) Technical Effect

As explained above, according to the impedance estimating apparatus in the first embodiment, it is possible to relatively easily estimate the value Z of the complex impedance corresponding to a desired temperature, by using the slope function indicating the relation between the value Z of the complex impedance and the inverse of the temperature T of the battery 10. Thus, for example, the complex impedance measured under any temperature condition can be converted to the value Z of the complex impedance corresponding to the predetermined reference temperature. In other words, without actually setting the temperature of the battery 10 at the predetermined reference temperature, it is possible to know the value Z of the complex impedance, which is to be measured when the battery 10 is at the predetermined reference temperature. As a result, the estimation of the state of the battery 10 using the value Z of the complex impedance, or similar operations, can be preferably performed.

The derived slope function does not change unless the configuration of the battery 10 changes. In other words, unless the battery 10 is replaced by a new one, the same slope function can be used to estimate the complex impedance. Thus, once the slope function is derived, it is not necessary to derive a new slope function at each time.

If a plurality of complex impedances of a plurality types of batteries 10 are estimated, a plurality of slope functions respectively corresponding to the plurality of types of batteries 10 may be used. In this case, the slope function may be newly derived in timing in which the type of the battery 10 is changed. Alternatively, the plurality of slope functions respectively corresponding to the plurality of types of batteries 10 may be derived and stored in advance, and a slope function that is to be used may be selected from them, as occasion demands.

In order to select the slope function that is to be used from the plurality of slope functions stored, the value Z of the complex impedance of the battery 10 may be measured under a temperature condition in which the measurement accuracy is ensured. The value Z of the complex impedance and the temperature T measured in this manner have high measurement accuracy and have accurate values. Thus, if a slope function that is established after the substitution of the values is found, it is possible to appropriately select the slope function to be used, i.e., the slope function corresponding to the battery 10 at that time.

### Second Embodiment

An impedance estimating apparatus according to a second embodiment will be explained. The second embodiment is partially different from the first embodiment in operation, and the other part is substantially the same. Thus, hereinafter, a different part from that of the first embodiment will be explained in detail, and an explanation of the same part will be omitted.

(1) Frequency Band Corresponding to Arc Component

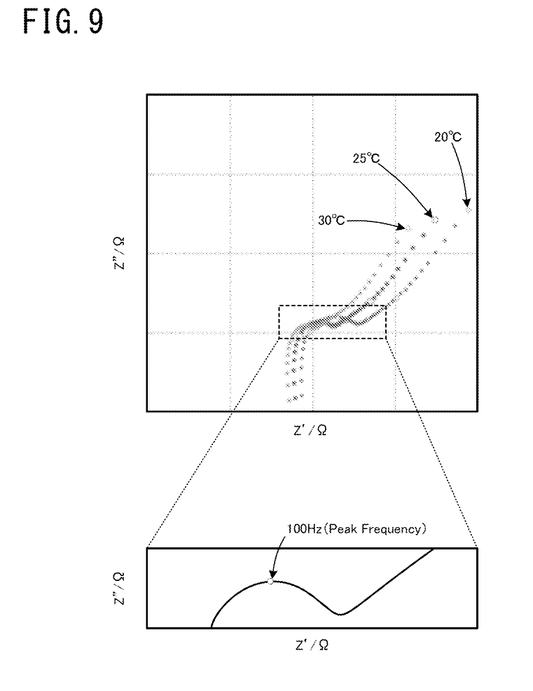

Firstly, a frequency band of the complex impedance targeted by the impedance estimating apparatus according to the second embodiment will be explained with reference to FIG. 9. FIG. 9 is a graph illustrating a partially enlarged arc component of a Cole-Cole plot.

As illustrated in FIG. 9, Cole-Cole plotted complex impedances include an arc component, i.e., a curved component with a relatively high frequency (refer to an enlarged part in FIG. 9), in addition to a slope component, which is a frequency band estimated by the impedance estimating apparatus according to the first embodiment, i.e., a linear component with a relatively low frequency.

The arc component of the Cole-Cole plotted complex impedances is located in a frequency area higher than an area that belongs to ion diffusion of the battery 10. The impedance estimating apparatus according to the second embodiment is configured to estimate the complex impedances in a frequency band corresponding to the arc component. An explanation below indicates that a peak frequency of the arc component to be estimated, i.e., a frequency corresponding to a highest part of the arc component, is 100 Hz.

(2) Explanation of Operation

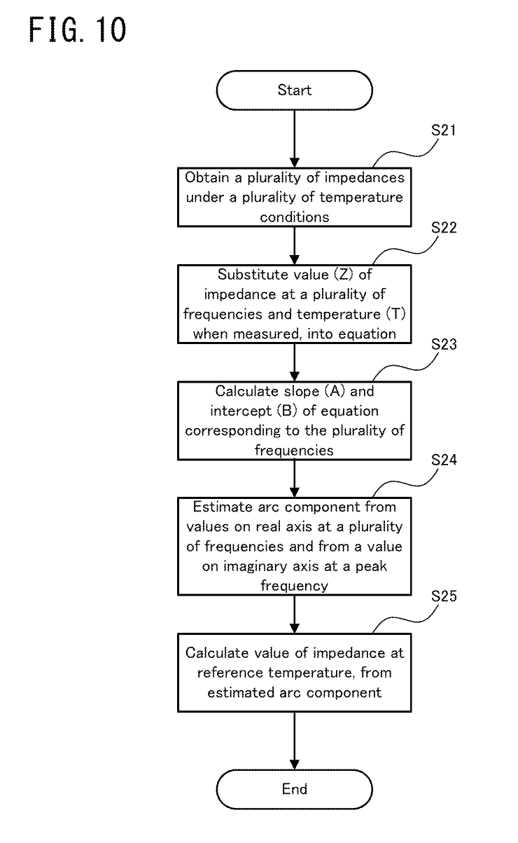

Operations performed by the impedance estimating apparatus according to the second embodiment will be explained with reference to FIG. 10. FIG. 10 is a flowchart illustrating a flow of the operations of the impedance estimating apparatus according to the second embodiment.

In FIG. 10, the impedance estimating apparatus according to the second embodiment obtains the values Z0 of the complex impedances of the battery 10 and the temperatures T0 of the battery 10 when the corresponding complex impedances are measured, under a plurality of temperature conditions (step S21).

The slope function calculator 130 then substitutes the values Z0 of the complex impedances at the predetermined frequency of the battery 10 and the temperatures T0 of the battery 10 when the corresponding complex impedances are obtained, into a numerical expression stored in advance (i.e., the numerical expression (1) described above) (step S22) and obtains the slope A and the intercept B (step S23), so that the slope function is derived.

A process performed to derive the slope function in the second embodiment is substantially the same as the process performed in the first embodiment (refer to the step S11 to the step S13 in FIG. 4). In the second embodiment, however, two types of slope functions, which are for the real component Z′ and the imaginary component Z″ of the complex impedance, may be derived. In the first embodiment, one slope function regarding the predetermined frequency may be calculated. In contrast, in the second embodiment, the slope function may be calculated for the real component Z′ of the complex impedance corresponding to each of a plurality of frequencies included in the frequency band corresponding to the arc component. In other words, a plurality of slope functions are derived for the real components Z′ of the complex impedances. On the other hand, one slope function for the imaginary component Z″ of the complex impedance corresponding to the peak frequency of the arc component (which is 100 Hz herein) may be derived.

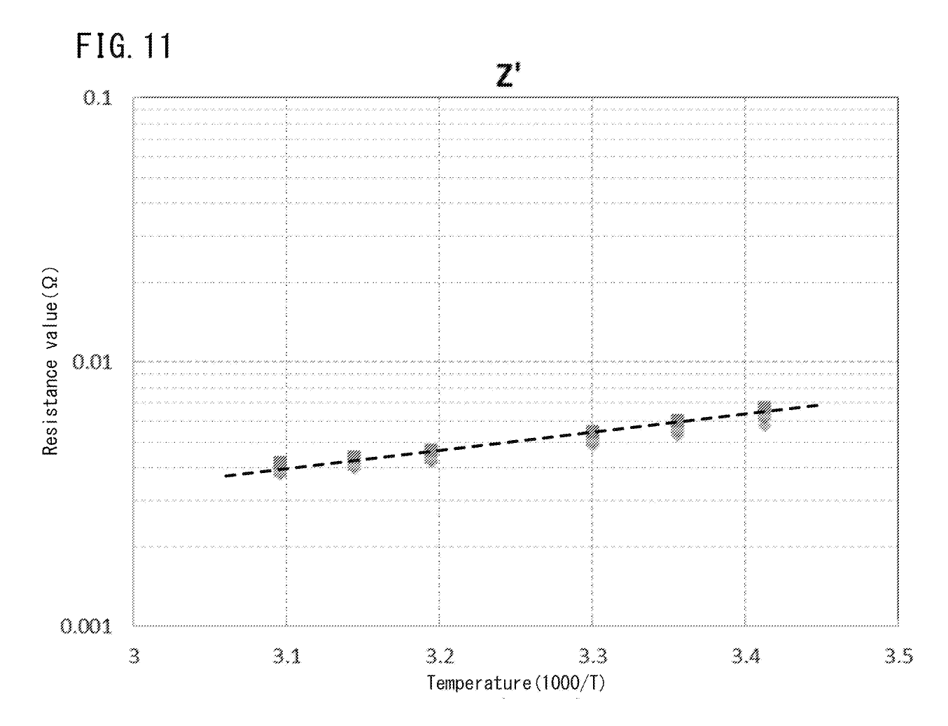

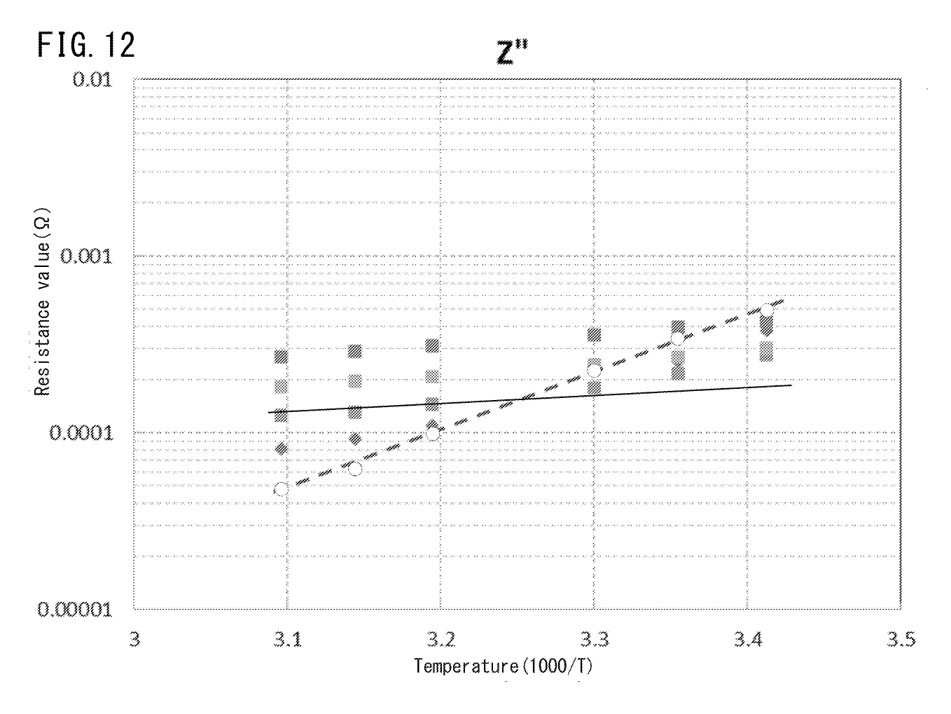

Here, with reference to FIG. 11 and FIG. 12, an explanation will be given to the reason why only the slope function for the imaginary component Z″ of the complex impedance corresponding to the peak frequency is derived. FIG. 11 is a graph illustrating a relation between the real component of the complex impedance and the inverse of the temperature in the frequency band corresponding to the arc component. FIG. 12 is a graph illustrating a relation between the imaginary component of the complex impedance and the inverse of the temperature in the frequency band corresponding to the arc component.

As illustrated in FIG. 11, the real component Z′ for the complex impedances of the arc component changes linearly with respect to a variation in the temperature T. In other words, it changes in the same manner as that of the real component Z′ for the complex impedances of the slope component illustrated in FIG. 6. Thus, for the real component Z′ of the complex impedance, it is possible to estimate an accurate value for each of the plurality of frequencies corresponding to the arc component by using the slope function as in the first embodiment. Thus, regarding the slope function for the real component Z′ of the complex impedance, a plurality of slope functions are derived for the plurality of frequencies corresponding to the arc component.

On the other hand, as illustrated in FIG. 12, the imaginary component Z″ for the complex impedances of the arc component does not change linearly with respect to the variation in the temperature T (refer to a solid line in FIG. 12). In other words, it changes in a different manner from that of the imaginary component Z″ for the complex impedances of the slope component illustrated in FIG. 7. Thus, for the imaginary component Z″ of the complex impedance, it is hardly possible to estimate an accurate value for each of the plurality of frequencies corresponding to the arc component even by using the slope function as in the first embodiment. However, the imaginary component Z″ of the complex impedance corresponding to the peak frequency of the arc component changes linearly with respect to the variation in the temperature T (refer to a dashed line in FIG. 12). Thus, only for the peak frequency, it is possible to estimate the accurate value by using the slope function. This is why only the slope function for the imaginary component Z″ of the complex impedance corresponding to the peak frequency is derived.

Back in FIG. 10, the impedance estimator 140 may use the plurality of slope functions for the real components Z′ of the complex impedances, thereby estimating the real component Z′ of the complex impedance corresponding to the predetermined reference temperature for each of the plurality of frequencies. Moreover, the impedance estimator 140 may use the slope function for the imaginary component Z″ of the complex impedance corresponding to the peak frequency of the arc component, thereby estimating the imaginary component Z″ corresponding to the predetermined reference temperature. Then, the impedance estimator 140 estimates the arc component of the complex impedances, which is specifically a shape of the arc component of the Cole-Cole plot, by using the estimated real component Z′ and the estimated imaginary component Z″ of the impedance (step S24).

For the real component Z′ of the complex impedance, a plurality of values are respectively estimated for the plurality of frequencies corresponding to the arc component. For the imaginary component Z″ of the complex impedance, however, only one value corresponding to the peak frequency of the arc component is estimated. In other words, for the imaginary component Z″ of the complex impedance, not all values corresponding to the plurality of frequencies corresponding to the arc component are estimated. However, a rough shape of the arc component, i.e., an upward arc shape as illustrated in FIG. 9, is already known. Thus, if the plurality of values of the real components Z′ of the complex impedances corresponding to the plurality of frequencies and one value of the imaginary component Z″ of the complex impedance corresponding to the peak frequency are known, the shape of the arc component can be accurately estimated.

The impedance estimator 140 uses the arc component of the complex impedance corresponding to the predetermined reference temperature, which is estimated in the above manner, thereby estimating the value Z of the complex impedance at any frequency corresponding to the arc component (step S25).

(3) Technical Effect

As explained above, according to the impedance estimating apparatus in the second embodiment, it is possible to estimate the complex impedance in the frequency band corresponding to the arc component of the Cole-Cole plot. In the frequency band corresponding to the arc component, as explained above, there is a part in which the slope function cannot be derived for the imaginary component Z″ of the impedance, i.e., there is a part in which the linear relation indicated by the slope function is not established. It is, however, possible to estimate the shape of the arc component of the complex impedance by using the imaginary component Z″ at the peak frequency at which the slope function can be used. As a result, it is possible to estimate the complex impedance corresponding to a desired temperature.

<Supplementary Notes>

Various aspects of embodiments of the present disclosure derived from the embodiments explained above will be explained hereinafter.

(Supplementary Note 1)

An impedance estimating apparatus described in Supplementary Note 1 is provided with: a deriving device configured to derive a slope function, on the basis of a value of a complex impedance of a battery at a predetermined frequency out of values obtained at a plurality of different temperatures and on the basis of a temperature of the battery when the complex impedance is obtained, wherein the slope function indicates a relation between the value of the complex impedance at the predetermined frequency and an inverse of the temperature of the battery; and an estimator configured to estimate a value of the complex impedance at the predetermined frequency corresponding to a desired temperature of the battery by using the slope function.

According to the impedance estimating apparatus described in Supplementary Note 1, the slope function may be derived on the basis of the value of the complex impedance of the battery at the predetermined frequency out of the values obtained at the plurality of different temperatures and on the basis of the temperature of the battery when the complex impedance is obtained. The slope function is derived as a function indicating the relation between the value of the complex impedance at the predetermined frequency and the inverse of the temperature of the battery. It is thus possible to estimate the value of the complex impedance at the predetermined frequency corresponding to the desired temperature of the battery by using the slope function. In other words, it is possible to estimate the complex impedance under a predetermined temperature condition, regardless of an actual temperature of the battery.

(Supplementary Note 2)

In an impedance estimating apparatus described in Supplementary Note 2, the deriving device is configured to use at least one of an absolute value and a real component of the complex impedance, as the value of the complex impedance at the predetermined frequency.

According to the impedance estimating apparatus described in Supplementary Note 2, by using at least one of the absolute value and the real component of the complex impedance, it is possible to estimate the complex impedance of the battery with relatively high accuracy, for example, in comparison with when an imaginary component of the complex impedance is used.

(Supplementary Note 3)

In an impedance estimating apparatus described in Supplementary Note 3, the slope function is expressed as a numerical expression, which his log Z=A×(1/T)+B, wherein A is a slope, B is an intercept, Z is the value of the complex impedance at the predetermined frequency, and T is the temperature of the battery.

According to the impedance estimating apparatus described in Supplementary Note 3, the slope function may be derived as a linear function. It is thus possible to extremely easily estimate the complex impedance of the battery.

(Supplementary Note 4)

In an impedance estimating apparatus described in Supplementary Note 4, the deriving device is configured to calculate another of the slope A and the intercept B, by using a temperature of the battery at which measurement accuracy is ensured and by using a value of the complex impedance at the predetermined frequency obtained at the temperature of the battery at which the measurement accuracy is ensured.

According to the impedance estimating apparatus described in Supplementary Note 4, it is possible to accurately calculate the slope A or the intercept B by using the temperature of the battery at which the measurement accuracy is ensured and by using the value of the complex impedance at the predetermined frequency obtained at the temperature at which the measurement accuracy is ensured.

(Supplementary Note 5)

In an impedance estimating apparatus described in Supplementary Note 5, the estimator is configured to store therein a plurality of slope functions respectively corresponding to a plurality of types of batteries, which are derived in advance by the deriving device, and the estimator is configured to determine the slope function that is used to estimate the value of the complex impedance at the predetermined frequency, from the plurality of slope functions stored, on the basis of a temperature at which measurement accuracy is ensured and on the basis of a value of the complex impedance at the predetermined frequency obtained at the temperature of the battery at which the measurement accuracy is ensured.

According to the impedance estimating apparatus described in Supplementary Note 5, an appropriate slope function according to the type of the battery whose complex impedance is to be estimated may be determined on the basis of the temperature at which the measurement accuracy is ensured and on the basis of the value of the complex impedance at the predetermined frequency obtained at the temperature of the battery at which the measurement accuracy is ensured. Thus, even if a plurality of types of batteries (or more specifically, a plurality of batteries in which different slope functions are derived) are targeted to estimate the complex impedances, it is possible to accurately estimate the complex impedances of the batteries.

(Supplementary Note 6)

An impedance estimating apparatus described in Supplementary Note 6 is provided with: a deriving device configured to derive a plurality of slope functions, on the basis of values of complex impedances of a battery at a plurality of frequencies out of values obtained at a plurality of different temperatures and on the basis of temperatures of the battery when the complex impedances are obtained, in a frequency area higher than an area of a Cole-Cole plot that belongs to ion diffusion, wherein each of the plurality of slope functions indicates respective one of relations between the values of the complex impedances at the plurality of frequencies and inverses of the temperatures of the battery; and an estimator configured (i) to estimate real components at the plurality of frequencies that form an arc component of the complex impedances by using the plurality of slope functions and to estimate an imaginary component at a peak frequency of the arc component of the complex impedances by using a slope function corresponding to the peak frequency from among the plurality of slope functions, (ii) to estimate the arc component of the complex impedances from the estimated real components and the estimated imaginary component, and (iii) to estimate a value of the complex impedance corresponding to a desired temperature of the battery from the estimated arc component.

According to the impedance estimating apparatus described in Supplementary Note 6, the complex impedances of the battery may be estimated in the frequency area higher than the area of the Cole-Cole plot that belongs to the ion diffusion. Specifically, firstly, the arc component of the complex impedances corresponding to the desired temperature of the battery may be estimated from the real components at the plurality of frequencies that form the arc component of the complex impedances and from the imaginary component at the peak frequency of the arc component of the complex impedances, by using the slope functions. Then, the value of the complex impedance at the predetermined frequency corresponding to the desired temperature of the battery may be estimated from the estimated arc component.

In the area of the Cole-Cole plot that belongs to the ion diffusion, the real component of the complex impedance has a constant relation between the value of the complex impedance and the inverse of the temperature of the battery; namely, the real component has a constant slope in the slope function. In contrast, the imaginary component of the complex impedance does not have a constant relation between the value of the complex impedance and the inverse of the temperature of the battery; namely, the imaginary component does not have a constant slope in the slope function. For the value at the peak frequency of the arc component of the complex impedances, however, the imaginary component of the complex impedance has a constant relation between the value of the complex impedance and the inverse of the temperature of the battery; namely, the imaginary component has a constant slop in the slope function.

It is therefore possible to accurately estimate the arc component of the complex impedances corresponding to the desired temperature of the battery, by using the real components at the plurality of frequencies that form the arc component of the complex impedances and by using the imaginary component at the peak frequency of the arc component of the complex impedances. If the arc component can be accurately estimated, the value of the complex impedance can be easily estimated.

The present disclosure may be embodied in other specific forms without departing from the spirit or essential characteristics thereof. The present embodiments and examples are therefore to be considered in all respects as illustrative and not restrictive, the scope of the disclosure being indicated by the appended claims rather than by the foregoing description and all changes which come in the meaning and range of equivalency of the claims are therefore intended to be embraced therein.

What is claimed is:

1. An impedance estimating apparatus comprising:
a deriving device configured to derive a slope function, on the basis of a value of a complex impedance of a battery at a predetermined frequency out of values obtained at a plurality of different temperatures and on the basis of a temperature of the battery when the complex impedance is obtained, wherein the slope function indicates a relation between the value of the complex impedance at the predetermined frequency and an inverse of the temperature of the battery; and
an estimator configured to estimate a value of the complex impedance at the predetermined frequency corresponding to a desired temperature of the battery by using the slope function.

2. The impedance estimating apparatus according to claim 1, wherein said deriving device is configured to use at least one of an absolute value and a real component of the complex impedance, as the value of the complex impedance at the predetermined frequency.

3. The impedance estimating apparatus according to claim 1, wherein the slope function is expressed as a numerical expression, which is log Z=A×(1/T)+B, wherein A is a slope, B is an intercept, Z is the value of the complex impedance at the predetermined frequency, and T is the temperature of the battery.

4. The impedance estimating apparatus according to claim 3, wherein if one of the slope A and the intercept B is known, said deriving device is configured to calculate another of the slope A and the intercept B, by using a temperature of the battery at which measurement accuracy is ensured and by using a value of the complex impedance at the predetermined frequency obtained at the temperature of the battery at which the measurement accuracy is ensured.

5. The impedance estimating apparatus according to claim 1, wherein
said estimator is configured to store therein a plurality of slope functions respectively corresponding to a plurality of types of batteries, which are derived in advance by said deriving device, and
said estimator is configured to determine the slope function that is used to estimate the value of the complex impedance at the predetermined frequency, from the plurality of slope functions stored, on the basis of a temperature at which measurement accuracy is ensured and on the basis of a value of the complex impedance at the predetermined frequency obtained at the temperature of the battery at which the measurement accuracy is ensured.

6. An impedance estimating apparatus comprising:
a deriving device configured to derive a plurality of slope functions, on the basis of values of complex impedances of a battery at a plurality of frequencies out of values obtained at a plurality of different temperatures and on the basis of temperatures of the battery when the complex impedances are obtained, in a frequency area higher than an area of a Cole-Cole plot that belongs to ion diffusion, wherein each of the plurality of slope functions indicates respective one of relations between the values of the complex impedances at the plurality of frequencies and inverses of the temperatures of the battery; and
an estimator configured (i) to estimate real components at the plurality of frequencies that form an arc component of the complex impedances by using the plurality of slope functions and to estimate an imaginary component at a peak frequency of the arc component of the complex impedances by using a slope function corresponding to the peak frequency from among the plurality of slope functions, (ii) to estimate the arc component of the complex impedances from the estimated real components and the estimated imaginary component, and (iii) to estimate a value of the complex impedance corresponding to a desired temperature of the battery from the estimated arc component.
